(19) United States
(12) Patent Application Publication
(10) Pub. No.: US 2026/0334315 A1
(43) Pub. Date: Oct. 22, 2026

(54) SIDE OF A DIE THAT IS COPLANAR WITH A SIDE OF A MOLDING

(71) Applicant: Intel Corporation, Santa Clara, CA (US)

(72) Inventors: Xavier F. BRUN, Chandler, AZ (US); Trianggono WIDODO, Hillsboro, OR (US)

(21) Appl. No.: 19/718,287

(22) Filed: Jun. 24, 2026

Related U.S. Application Data
(63) Continuation of application No. 19/630,046, filed on Mar. 26, 2026.
Application No. 19/630,046 is a continuation of application No. 17/956,760, filed on Sep. 29, 2022.

(51) Int. Cl. H10W 90/00; H10W 20/20; H10W 70/60; H10W 70/685; H10W 74/01; H10W 74/10

(52) U.S. Cl. CPC H10W 90/00; H10W 20/20; H10W 70/611; H10W 70/685; H10W 74/01; H10W 74/117; H10W 90/701; H10W 90/724

(57) ABSTRACT

Embodiments herein relate to systems, apparatuses, or processes creating a package that includes a die embedded in a molding, where a surface of the die is coplanar with a surface of the molding. During a stage of package manufacture, the die may have a finished side that may be coupled with a component of the package, and an unfinished side. During a subsequent stage of package manufacture, molding may be placed around the die, and then the molding and at least a portion of the die may be planarized, which may involve grinding and polishing. The planarization may reveal one or more TSV at the side of the die which is now finished and ready for electrical coupling with other components. As a result, a side of the molding at a side of the die to be coplanar. Other embodiments may be described and/or claimed.

### CROSS-REFERENCE TO RELATED APPLICATIONS

This application is a continuation of U.S. patent application Ser. No. 19/630,046, filed Mar. 26, 2026, which is a continuation of pending U.S. patent application Ser. No. 17/956,760, filed on Sep. 29, 2022, the entire contents of which are hereby incorporated by reference herein.

### FIELD

Embodiments of the present disclosure generally relate to the field of package assemblies, and in particular package assemblies that include dies within a layer of molding.

### BACKGROUND

Continued reduction in end product size of mobile electronic devices such as smart phones and ultrabooks is a driving force for the development of reduced size system in package components. Reducing the number of stages in a manufacturing process for package components will reduce the overall cost of packages.

### BRIEF DESCRIPTION OF THE DRAWINGS

FIGS. 1A-1C illustrate a cross section side view of a legacy package and a legacy die, and a cross section side view of a legacy stage in the manufacturing process for embedding a die that is electrically coupled with another die within a package.

FIG. 2 illustrates a cross section side view of a package that includes an embedded die with a side that is coplanar with a side of a molding layer and is electrically coupled with another die, in accordance with various embodiments.

FIGS. 3A-3D illustrate cross section side views of stages in a manufacturing process for creating an embedded die with a side that is coplanar with a side of a molding layer and is electrically coupled with another die, in accordance with various embodiments.

FIG. 4 illustrates a top-down view of a package that includes an embedded die with a side that is coplanar with a side of a molding layer and is electrically coupled with another die, in accordance with various embodiments.

FIGS. 5A-5C illustrate a cross section side view of a legacy package and a legacy die, and a cross section side view of a legacy stage in the manufacturing process for embedding a die that is electrically coupled with a side of the package.

FIG. 6 illustrates a cross section side view of a package that includes an embedded die that is coplanar with a side of a molding layer and is electrically coupled with a side of the package, in accordance with various embodiments.

FIGS. 7A-7D illustrate cross section side views of stages in a manufacturing process for creating an embedded die with a side that is coplanar with a side of a molding layer and is electrically coupled with a side of the package, in accordance with various embodiments.

FIG. 8 illustrates a cross section side view of a legacy package that includes a plurality of dies embedded within the package that are coupled with top dies.

FIG. 9 illustrates a cross section side view of a package that includes a plurality of dies embedded within a layer of molding, where a side of the molding is coplanar with a side of each of the plurality of dies, and wherein the plurality of dies are coupled with top dies, in accordance with various embodiments.

FIGS. 10A-10F illustrate cross section side views of stages in a manufacturing process for creating a plurality of dies embedded within a layer of molding, where a side of the molding is coplanar with a side of each of the plurality of dies, in accordance with various embodiments.

FIG. 11 illustrates a top-down view of a package that includes a plurality of dies embedded within a layer of molding, where a side of the molding is coplanar with a side of each of the plurality of dies, and wherein the plurality dies are coupled with top dies, in accordance with various embodiments.

FIG. 12 illustrates an example of a process for creating an embedded die with a side that is coplanar with a side of a molding layer and is electrically coupled with another die, in accordance with various embodiments.

FIG. 13 schematically illustrates a computing device, in accordance with various embodiments.

### DETAILED DESCRIPTION

Embodiments of the present disclosure may generally relate to systems, apparatus, techniques, and/or processes directed to creating a package that includes multiple embedded dies, which may be referred to as chiplets. In embodiments, these embedded dies may have a front side and a back side opposite the front side, where the front side is proximate to functional circuitry within the die, and one or more through silicon vias (TSV) extend from the front side of the die toward the back side of the die. In embodiments, the front side of the die may be finished and be ready to immediately couple with circuitry during the manufacturing process, but the backside of the die may be unfinished, where TSVs at the backside of the die have not been revealed.

In embodiments, the unfinished backside of the die may cause the die to be taller during initial package assembly that it is in the final package. During the manufacturing process, a molding, which may be an epoxy molding compound (EMC), may be placed around the die and over the unfinished backside. A subsequent planarization process may then finish the backside of the die and expose the TSV at the backside of the die that are now ready for coupling with other circuitry. In embodiments, the planarization process may include grinding and/or polishing to planarize a surface of the molding so that it is coplanar with the backside of the die.

In embodiments, manufacturing dies that are to be embedded within a package that have unfinished backsides may save stages in the manufacturing process. For example, using only legacy dies that are finished on both sides may have slight variations in height that may cause misalignment of various layers of the package during manufacture. In addition, the reveal process that may be used to finish the second side of a legacy die requires an additional manufacturing stage when manufacturing the die. In embodiments with dies that have unfinished backsides, this additional stage is saved.

In embodiments, because the planarization reveals the TSV of the backside of the die, it is then immediately available for electrical connections, or features of a redistribution layer (RDL), to be applied directly on the backside of the die. In this way, only one side of the die has to be have bumps or other features attached prior to the embedding stage within the package. In embodiments, this process may be referred to as a single reveal process.

As the need for specialty chips with complex designs and tasks increases, monolithic chip design with a sustainable yield becomes an increasing challenge for chip designers and manufacturers. In order to overcome this challenge, die disaggregation enables incorporation of multispecialty dies, or chiplets, into a single packaging by leveraging advanced packaging architectures. Examples of these architectures include Foveros™ Omni™ from Intel.

In legacy implementations, electrical connections between the top dies, or tiles, and a base complex are formed either through pillars on the base complex for Foveros™ Omni™ or through TSVs on the base wafer for Foveros architecture. Legacy Foveros™ Omni™ manufacturing process reveals embedded TSV and mid-level bumps (MLB) of the base complex, for example micro pillars and silicon interface bumps (SIB) of a chiplet within a separate process for each chiplet prior to assembly within the package. Each chiplet is then attached through a separate bumping process. This legacy process, which requires an additional bump and reveal, causes challenges with thermal requirements, bump quality, chiplet height variation, in particular when coming from different vendors, and reveal variation, which may impact overall package yield. Legacy processes also require silver and tin, which has a thermal performance that is very different than embodiments described herein that use copper on copper. Legacy processes also introduce higher manufacturing cost.

In embodiments described herein, part of the reveal for a die may be combined into a stage of package manufacturing after the die is attached.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

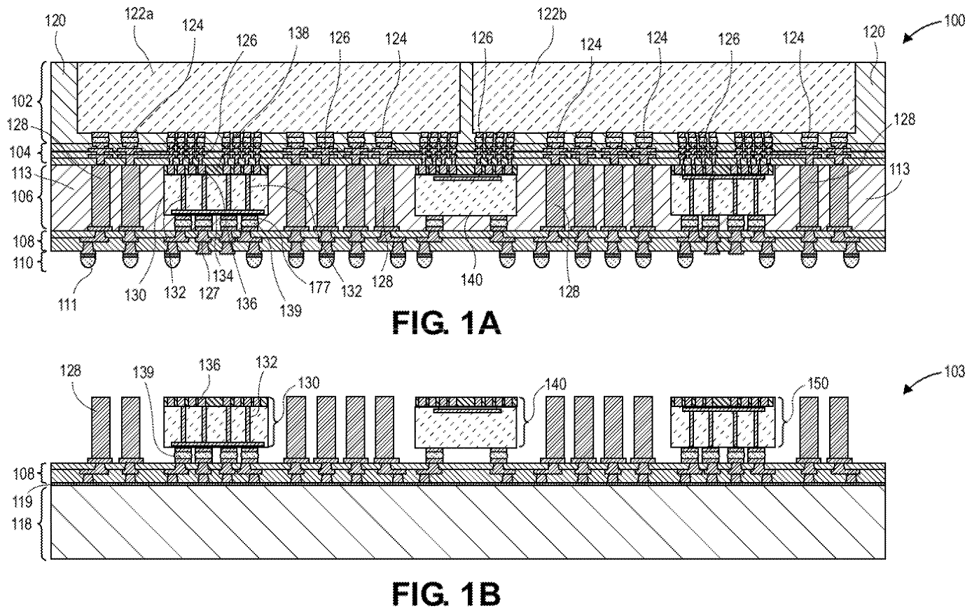

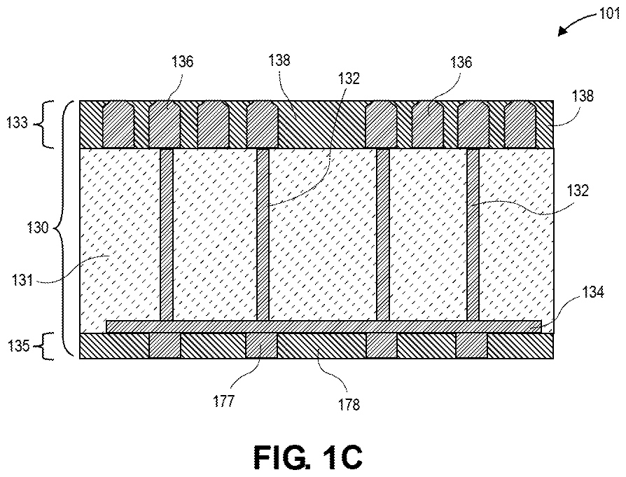

FIGS. 1A-1C illustrate a cross section side views of a legacy package and a legacy die, and a cross section side view of a legacy stage in the manufacturing process for embedding a die that is electrically coupled with another die within a package. Legacy package 100 of FIG. 1A shows a cross section side view that includes a BGA layer 110, a first RDL 108, mid-layer 106, a second RDL 104, and a top die layer 102. In implementations, the top die layer 102 may include dies 122a, 122b that may be electrically coupled through bumps 124, which may be micro bumps, to the second RDL 104. In implementations, a molding 120 may at least partially encapsulate or surround the dies 122a, 122b and the bumps 124.

The second RDL 104 may include various electrically conductive features that electrically couple the dies 122a, 122b with the mid-layer 106. In implementations, the mid-layer 106 may include copper pillars 128 that electrically couple the second RDL 104 with the first RDL 108. In implementations, the mid-layer 106 may include legacy dies 130, 140, 150, which may also be referred to as chiplets, that electrically couple with the second RDL 104 and the first RDL 108. In implementations, the legacy die 130 may include bumps 136 that are surrounded by a molding 138, that were formed prior to the legacy die 130 being placed into the legacy package 100.

Diagram 101 of FIG. 1C shows an enlarged view of legacy die 130 of FIG. 1A. In implementations, bumps 177, which may be surrounded by a molding 178, may electrically couple with a front side routing layer 134 that is coupled with functional circuitry (not shown) within the legacy die 130. In embodiments, the front side routing layer 134 may also electrically couple with one or more TSV 132. The TSV 132 may electrically couple with bumps 136 at a back side of the legacy die 130 next to the die body 131. In embodiments, a molding 138 may surround the bumps 136 and be on top of the die body 131. In implementations, the bumps 136, 177 may be micro bumps that include either copper or solder. In implementations, the bumps 136 and the molding 138 form a layer 133 at a top surface, or the back side, of the legacy die 130. The bumps 177 and the molding 178 form a layer 135 at a bottom surface, or the front side, of the legacy die 130. The TSV 132 only extends between the layer 133 and the layer 135. In implementations, the layer 133 and the layer 135 are formed when the legacy die 130 was created, or finished, prior to installation into legacy package 100.

Returning to legacy package 100 of FIG. 1A, for legacy die 130, the bumps 136 may electrically couple with one or more of the electrically conductive features 126 of the second RDL 104, and the bumps 177 at the front side routing layer 134 may electrically couple with electrically conductive features 139. As shown, legacy dies 140, 150 may be similar to legacy die 130, except the legacy die 140 has no TSV similar to TSV 132. In implementations, electrically conductive features 139 may be electrically coupled with electrical routing features 127 within the first RDL 108, which in turn may be electrically coupled with BGA 111 within the BGA layer 110.

A molding layer 113 may be included in mid-layer 106, and surround the copper pillars 128, and the legacy dies 130, 140, 150. In some legacy implementations, the molding 138 may not be present, and the molding layer 113 may be flowed around the electrically conductive features 139. Note that in legacy implementations, the TSV 132 do not directly electrically couple with the second RDL 104.

Diagram 103 of FIG. 1B shows a stage in the legacy manufacturing process where the first RDL 108 has been placed on a temporary carrier 118 using an adhesive layer 119. In implementations, the temporary carrier 118 may be a glass carrier. Legacy dies 130, 140, 150 have been previously prepared, and then placed onto the first RDL 108 using electrically conductive features 139 coupled with the first RDL 108. Subsequent to this stage in the legacy manufacturing process, a molding (not shown, but may be similar to molding layer 113) may then be applied and then planarized to reveal the bumps of the legacy dies 130, 140, 150, which may be similar to bumps 136 of die 130.

In these legacy implementations, each individual legacy die 130, 140, 150 has to go through a processing step by which bumps 177 at the front side are prepared, and bumps 136 at the back side are prepared and are electrically coupled with the TSV 132 prior to manufacture.

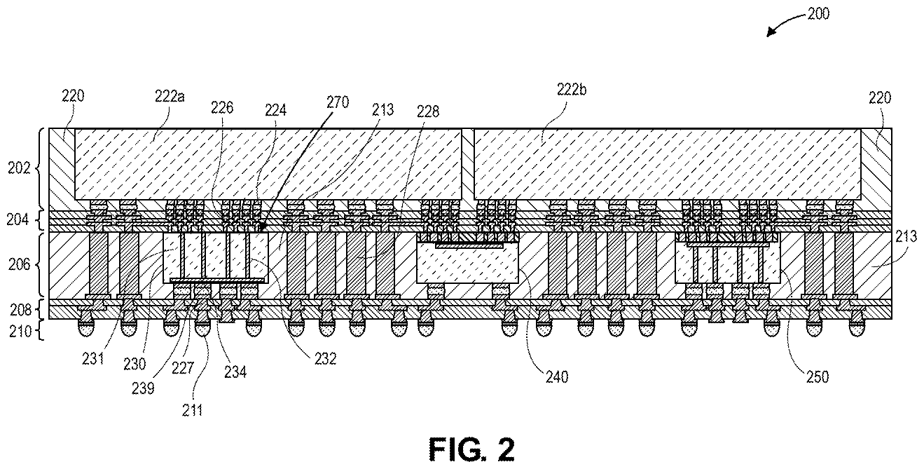

FIG. 2 illustrates a cross section side view of a package that includes an embedded die with a side that is coplanar with a side of a molding layer and is electrically coupled with another die, in accordance with various embodiments. Package 200, which may be similar to legacy package 100 of FIG. 1A, includes BGA layer 210, which may include solder balls, a first RDL 208, mid-layer 206, a second RDL 204, and a top die layer 202. In embodiments, the top die layer 202 may include dies 222a, 222b that may be electrically coupled through electrical connections 224 to the second RDL 204. In implementations, a molding 220 may at least partially encapsulate the dies 222a, 222b and the electrical connections 224.

The second RDL 204 may include various electrically conductive features 226, which may be referred to as electrical connectors, that may electrically couple the dies 222a, 222b with the mid-layer 206. In embodiments, the mid-layer 206 may include copper pillars 228 that electrically couple the second RDL 204 with the first RDL 208. In embodiments, the mid-layer 206 may include die 230 and dies 240, 250, which may similar to legacy dies 130, 140, 150 of FIG. 1, that electrically couple with the second RDL 204 and the first RDL 208. A molding 213 may partially surround the dies 230, 240, 250.

Die 230 includes a die body 231 and a plurality of TSV 232 that extend from a front side routing layer of the die 234 to the second RDL 204. In particular, there is no molding 213 between the die body 231 and the bottom of the second RDL 204, as shown at location 270. In embodiments, the second RDL 204, may be applied directly onto the die body 231, and directly electrically couple with TSV 232.

In embodiments, electrical features 239 may be electrically couple with electrical features 227 within the first RDL 208, which may in turn be electrically coupled with BGA 211 within the BGA layer 210. In embodiments, the molding 213 may be included in mid-layer 206, and may completely surround the copper pillars 228, which may be any electrically conductive pillar, the dies 230, 240, 250, and the electrical features 239.

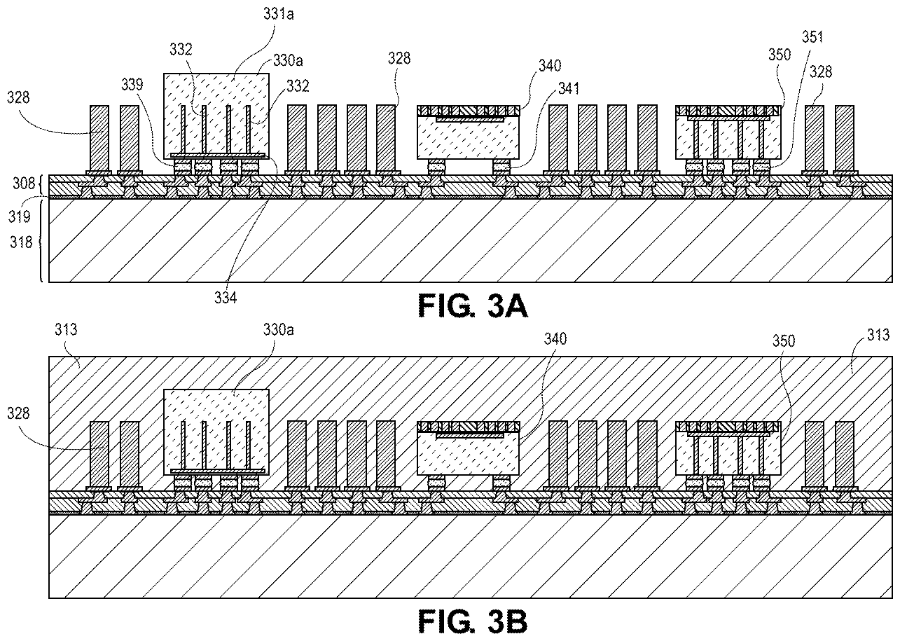

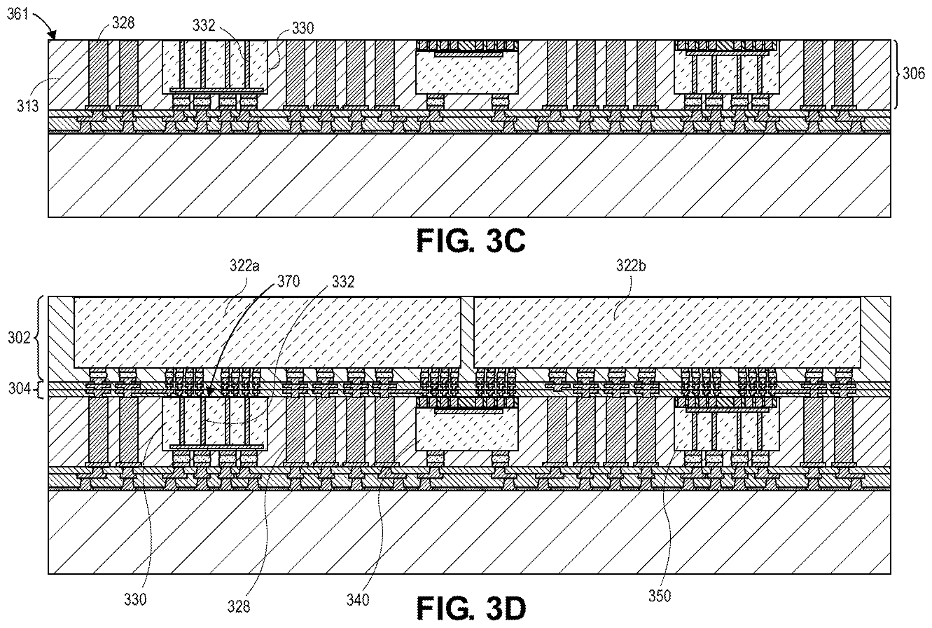

FIGS. 3A-3D illustrate cross section side views of stages in a manufacturing process for creating an embedded die with a side that is coplanar with a side of a molding layer and is electrically coupled with another die, in accordance with various embodiments. FIG. 3A shows a cross section side view of a stage in the manufacturing process, which may be similar to diagram 103 of FIG. 1B, that includes a temporary carrier 318 that is coupled with a first RDL 308, which may be similar to first RDL 208 of FIG. 2, using an adhesive 319.

Dies 340, 350, which may be legacy dies similar to legacy dies 140, 150 of FIG. 1A, are electrically and physically coupled with the first RDL 308 using electrical connections 341, 351. Die 330a, which may be similar to die 230 of FIG. 2, may be coupled with the first RDL 308 using electrically conductive features 339 at a front side routing layer of the die 334, which may be similar to front side routing layer 134 of FIG. 1A. Die 330a includes a plurality of TSV 332 that extend from the front side of the die 334. In embodiments, the die body 331a, which may include a molding material or may be silicon, may extend beyond the plurality of TSV 332 because the die 330a has an unfinished side that has not been revealed. Note that in embodiments, a height of the die 330a may be taller than a height of the other dies 340, 350 due to a side of the die 330a being unfinished, or not revealed.

FIG. 3B illustrates a cross section side view of a stage in the manufacturing process where a molding 313 is placed over the copper pillars 328, the die 330a, and dies 340, 350. In embodiments, the molding 313 may be placed using various techniques. The molding 313 materials can be a sheet, can be liquid, or can be granular. Depending on the materials used, the molding 313 can be laminated, spun on, or compression molded prior to curing. In embodiments, the molding may include epoxy, fillers, plasticizers, stabilizers, and the like.

FIG. 3C illustrates a cross section side view of a stage in the manufacturing process where a planarization process occurs to create plane 361 along the surface of the molding 313, the copper pillars 328, and dies 340, 350 to create substantially planar surfaces. In embodiments, the planarization process will also cause die 330a of FIG. 3B to become die 330, where the planarization process exposes the TSV 332. As a result, a side of the die 330 is coplanar with a surface of the molding 313. In embodiments, the molding 313, copper pillars 328, and dies 330, 340, 350 form a mid-layer 306, which may be similar to mid-layer 206 of FIG. 2.

FIG. 3D illustrates a cross section side view of a stage in the manufacturing process where the second RDL 304, which may be similar to second RDL 204 of FIG. 2, is placed on top of the mid-layer 306 which includes dies 330, 340, 350 and the copper pillars 328. Subsequently, the top die layer 302, which may be similar to top die layer 202 of FIG. 2, may include dies 322a, 322b, which may be similar to dies 222a, 222b of FIG. 2, may be placed on the second RDL 304. Note that the TSV 332 of die 330 directly electrically couple with the second RDL 304, as shown at location 370, which may be similar to location 270 of FIG. 2.

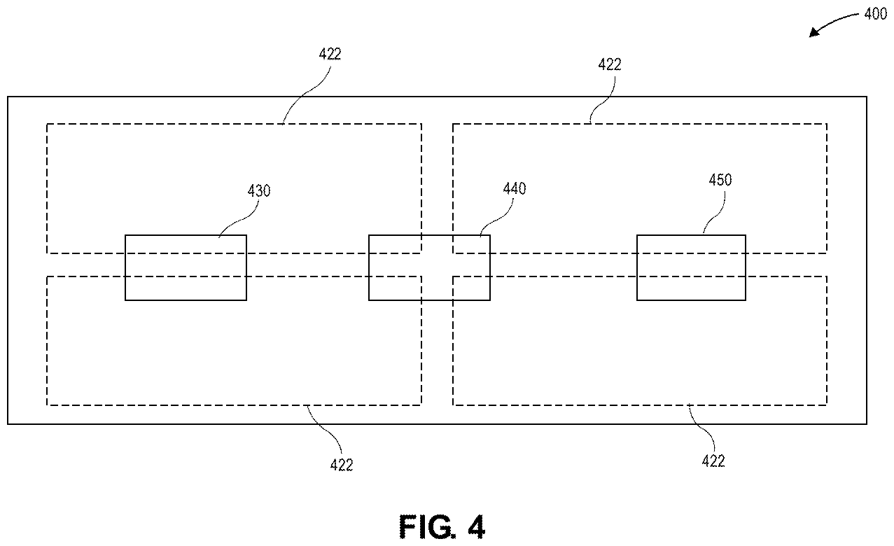

FIG. 4 illustrates a top-down view of a package that includes an embedded die with a side that is coplanar with a side of a molding layer and is electrically coupled with another die, in accordance with various embodiments. Package 400 shows a top-down view of the plurality of top dies 422, which may be similar to dies 222a, 222b of FIG. 2 or may be similar to dies 322a, 322b of FIG. 3D, that are electrically coupled with dies 430, 440, 450, where die 430 is similar to die 330 of FIGS. 3C-3D, or similar to die 230 of FIG. 2, and dies 440, 450 may be similar to dies 340, 350 of FIG. 3C. In embodiments, each of the dies 430, 440, 450 may be coupled with more than one of the plurality of top dies 422. In embodiments, the plurality of top dies 422, may be either have bumps (not shown, but which may be similar to electrical connections 224 of FIG. 2) or may have no bumps. In embodiments, no molding material may be required when bumps are not present,

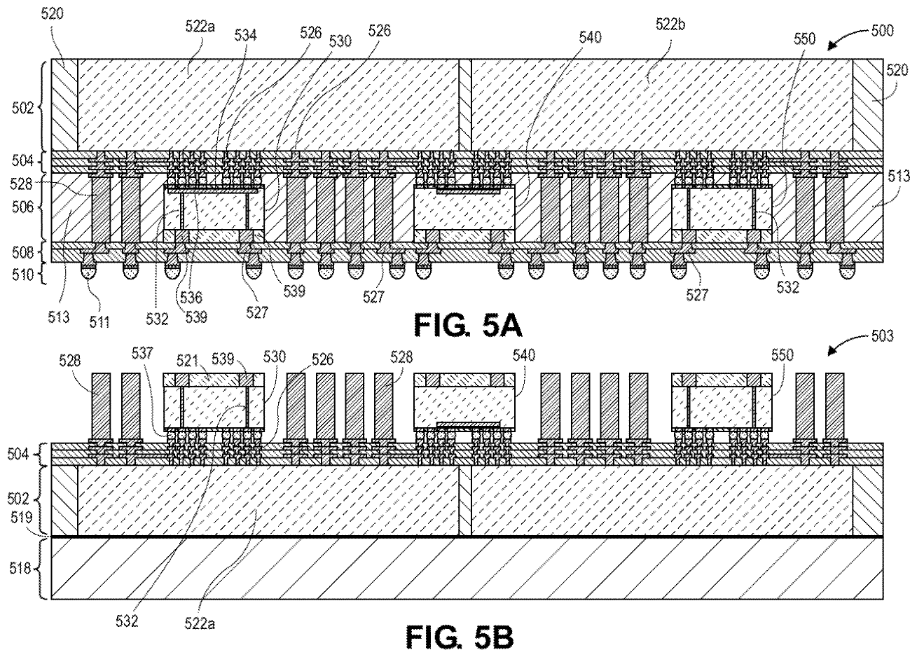

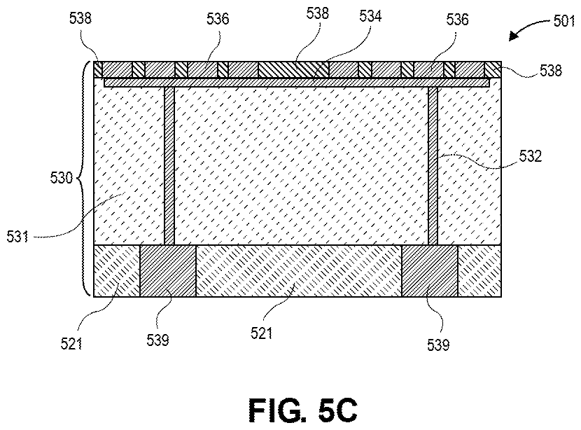

FIGS. 5A-5C illustrate a cross section side view of a legacy package and a legacy die, and a cross section side view of a legacy stage in the manufacturing process for embedding a die that is electrically coupled with a side of the package. Legacy package 500 of FIG. 5A shows a cross section side view that includes a BGA layer 510, a first RDL 508, mid-layer 506, a second RDL 504, and a top die layer 502. In implementations, the top die layer 502 may include dies 522a, 522b that may be electrically couple to the second RDL 504. In implementations, a molding 520 may at least partially encapsulate the dies 522a, 522b.

The second RDL 504 may include various electrically conductive features 526, which may be referred to as electrical connectors, that electrically couple the dies 522a, 522b with the mid-layer 506. In implementations, the mid-layer 506 may include copper pillars 528 that electrically couple the second RDL 504 with the first RDL 508. In implementations, the mid-layer 506 may include legacy dies 530, 540, 550, which may also be referred to as chiplets, that electrically couple with the second RDL 504 and the first RDL 508.

Diagram 501 of FIG. 5C shows an enlarged view of legacy die 530. In implementations, a front side routing layer 534 may electrically couple with functional circuitry (not shown) within the legacy die 530, and may also electrically couple with one or more TSV 532 that extend through the die body 531 to electrically conductive features 539, which may be pads, at a back side of the legacy die 530. In implementations, the electrically conductive features 539 may include copper. The front side routing layer 534 may electrically couple with bumps 536. In embodiments, a molding layer 538 may surround the bumps 536. In implementations, the bumps 536 may be micro bumps that include either copper or solder.

Returning to legacy package 500 of FIG. 5A, for legacy die 530, the bumps 536 may electrically couple with one or more of the electrically conductive features 526 of the second RDL 504, and the TSV 532 may electrically couple with electrically conductive features 539. As shown, legacy dies 540, 550 may be similar to legacy die 530, except the legacy die 540 has no TSV similar to TSV 532. In implementations, electrical routing features 527 may be electrically coupled within the first RDL 508, which may in turn be electrically coupled with BGA 511 within the BGA layer 510. A molding 513 may be included in mid-layer 506, and surround the copper pillars 528, the legacy dies 530, 540, 550, and the electrically conductive features 539.

Diagram 503 of FIG. 5B shows a stage in the legacy manufacturing process where the top die layer 502, that includes dies 522a, 522b, has been attached to a temporary carrier 518 using an adhesive layer 519. In implementations, the temporary carrier 518 may be a glass carrier. Legacy dies 530, 540, 550 have been previously prepared, and then placed onto electrically conductive features 537, which may be micro bumps, that are coupled onto the electrically conductive features 526 within the second RDL 504. Copper pillars 528 may be placed on the second RDL 504.

Subsequent to the stage shown in diagram 503, a molding (not shown, but may be similar to molding 513) may be placed to encapsulate the copper pillars 528 and the legacy dies 530, 540, 550. In these legacy implementations, each individual legacy die 530, 540, 550 has to go through a processing step by which electrically conductive features 539 are coupled with the TSV 532, and surrounded by molding 521. In embodiments, the molding 513 and the molding 521 may be a same molding.

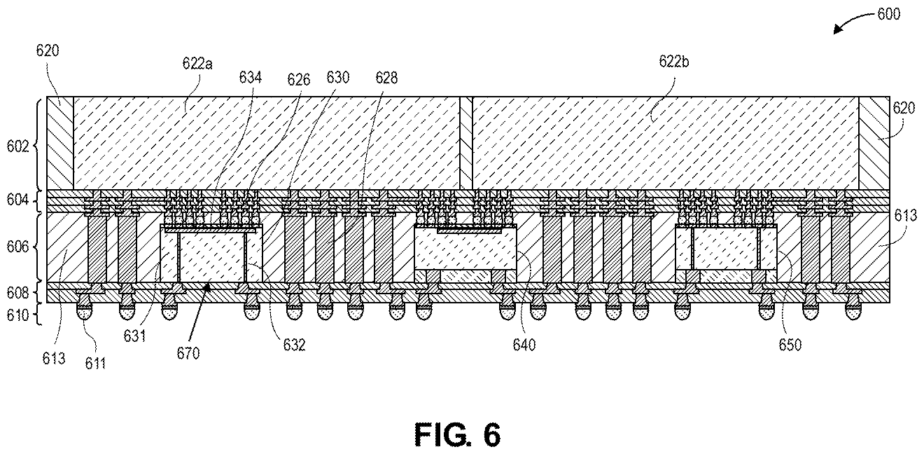

FIG. 6 illustrates a cross section side view of a package that includes an embedded die that is coplanar with a side of a molding layer and is electrically coupled with a side of the package, in accordance with various embodiments. Package 600, which may be similar to legacy package 500 of FIG. 5A, includes BGA layer 610, a first RDL 608, mid-layer 606, a second RDL 604, and a top die layer 602. In embodiments, the top die layer 602 may include dies 622a, 622b that may be electrically coupled to the second RDL 604. In implementations, a molding 620 may at least partially encapsulate the dies 622a, 622b.

The second RDL 604 may include various electrically conductive features 626, which may be referred to as electrical connectors, that electrically couple the dies 622a, 622b with the mid-layer 606. In implementations, the mid-layer 606 may include copper pillars 628 that electrically couple the second RDL 604 with the first RDL 608. In implementations, the mid-layer 606 may include dies 630, 640, 650, which may similar to legacy dies 530, 540, 550 of FIG. 5A, that may electrically couple with the second RDL 604 and the first RDL 608.

Die 630 includes a die body 631 and a plurality of TSV 632 that extend from a front side layer 634 to the first RDL 608. In particular, there is no molding material between the die body 631 and the first RDL 608, as shown in location 670. In embodiments, the first RDL 608, which may be referred to as one or more electrical contacts, may be applied directly onto the die body 631, and may electrically couple directly with the TSV 632, which may in turn be electrically coupled with BGA 611 within the BGA layer 610. In embodiments, a molding layer 613 may be included in mid-layer 606, and may completely surround the copper pillars 628, and the dies 630, 640, 650, but will not be between die 630 and the first RDL 608. As a result a surface of the molding layer 613 may be coplanar with a surface of the die body 631 at the first RDL 608.

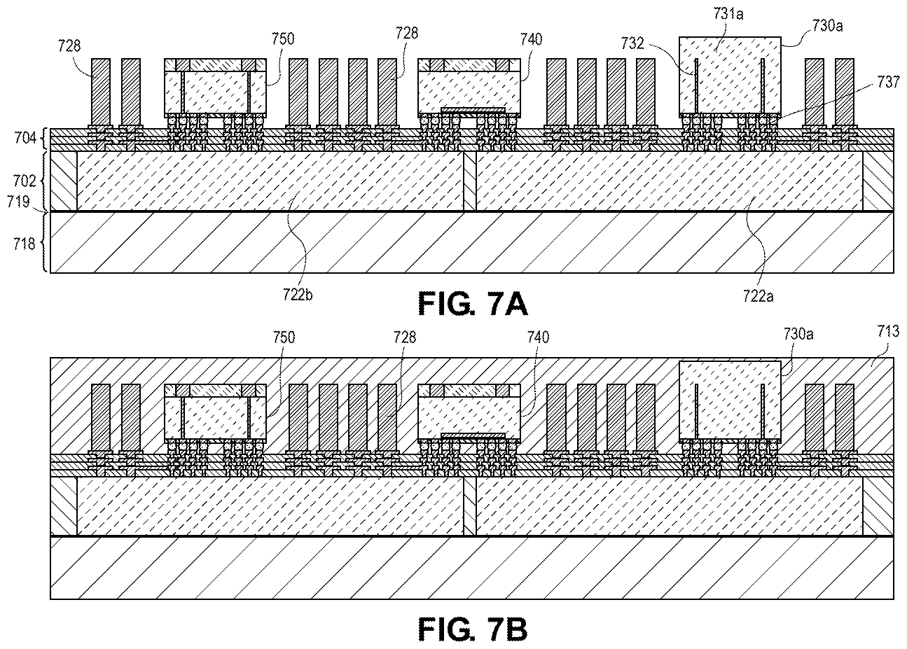

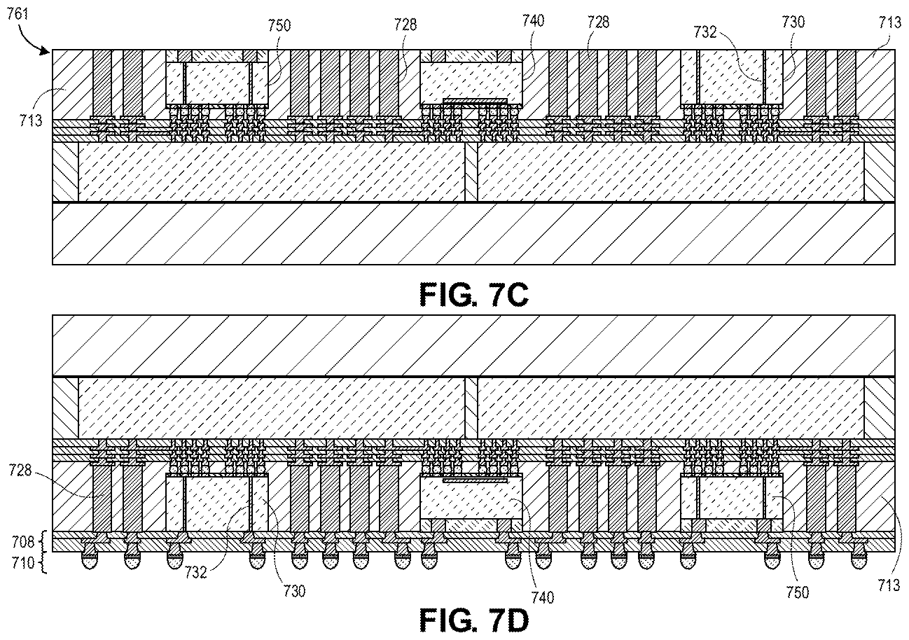

FIGS. 7A-7D illustrate cross section side views of stages in a manufacturing process for creating an embedded die with a side that is coplanar with a side of a molding layer and is electrically coupled with a side of the package, in accordance with various embodiments. FIG. 7A illustrates a cross section side view of a stage in a manufacturing process where a temporary carrier 718, which may be a glass carrier, is coupled with a top die layer 702 that includes top dies 722a, 722b using an adhesive 719.

Dies 740, 750 which have been previously prepared, are placed onto electrically conductive features 737, which may be micro bumps, that are coupled onto second RDL 704. Copper pillars 728 may be placed on the second RDL 704.

In embodiments, die 730a, which may be similar to die 630 of FIG. 6, may be placed on the second RDL 704. In embodiments, the die body 731a may extend beyond a length of the TSV 732 because the die 730a has an unfinished side. In embodiments, the die 730a may have an overall greater height than dies 740, 750. Note that unlike diagram 501 of FIG. 5C that showed legacy die 530 that included electrically conductive features 539 surrounded by a molding 521, die 730a of FIG. 7A is unfinished and does not have these features.

FIG. 7B illustrates a cross section side view of a stage in the manufacturing process where a molding 713 is placed over the copper pillars 728, the die 730a, and dies 740, 750. In embodiments, the molding may be similar to molding 313 of FIG. 3B.

FIG. 7C illustrates a cross section side view of a stage in the manufacturing process where a planarization process occurs to create plane 761 along the surface of the molding 713, the copper pillars 728, and dies 740, 750. In embodiments, the planarization process will also cause die 730a of FIG. 7B to become die 730, where the planarization process exposes the TSV 732 within the die 730.

FIG. 7D illustrates a cross section side view of a stage in the manufacturing process where a first RDL 708, which may be similar to first RDL 608 of FIG. 6, may be applied onto a surface of the molding 713, the copper pillars 728, and the dies 730, 740, 750. In embodiments, the first RDL 708 may be directly applied to the surface of the die 730 and electrically couple with TSV 732 within the die 730. In embodiments, a BGA layer 710, that may be similar to BGA layer 610 of FIG. 6, may be applied onto the first RDL 708.

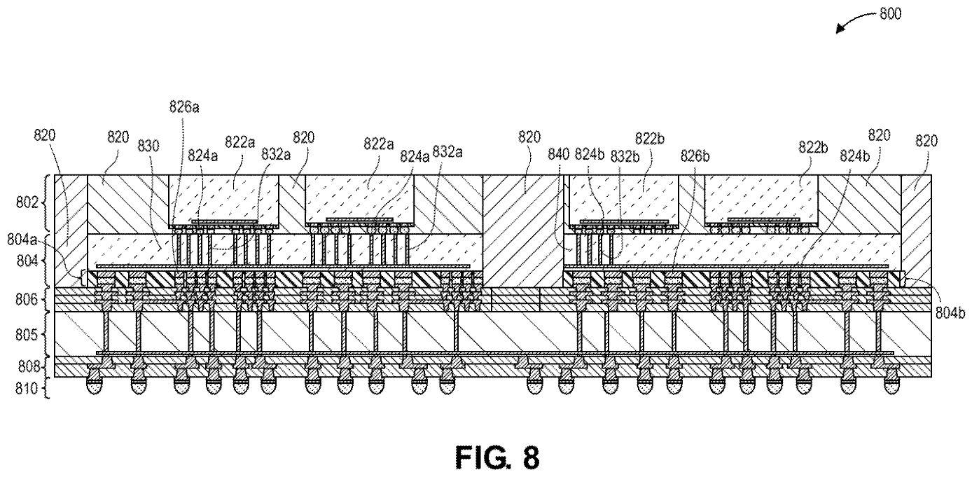

FIG. 8 illustrates a cross section side view of a legacy package that includes a plurality of dies embedded within the package that are coupled with top dies. Package 800 is a cross section side view that includes a BGA layer 810, a first RDL 808, an intermediate layer 805, which may include a die or a substrate, second RDL 806, a mid-die level 804, and a top die layer 802. In implementations, the mid-die level 804 may include a first mid-die 830 that is electrically and physically coupled with the second RDL 806 using a connection layer 804a, and a second mid-die 840 that is electrically and physically coupled with the second RDL 806 using a connection layer 804b.

In legacy implementations, the first mid-die 830 is completely formed prior to being attached to the second RDL 806 using bumps 826a. Similarly, the second mid-die 840 is completely formed prior to being attached to the second RDL 806 using bumps 826b.

In implementations, top dies 822a may be attached to the first mid-die 830 using bumps 824a, and top dies 822b may be attached to the second mid-die 840 using bumps 824b. In implementations, the bumps 824a may electrically couple with TSV 832a within the first mid-die 830, and the bumps 824b may electrically couple with TSV 832b within the second mid-die 840. Subsequently, a molding 820 may be applied that surrounds the first mid-die 830, the second mid-die 840, the top dies 822a, 822b, and extends down to the second RDL 806.

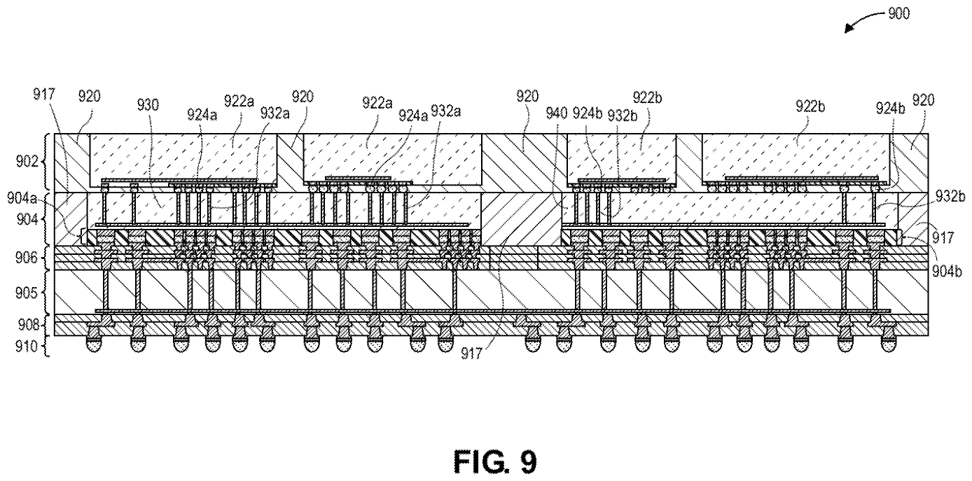

FIG. 9 illustrates a cross section side view of a package that includes a plurality of dies embedded within a layer of molding, where a side of the molding is coplanar with a side of each of the plurality of dies, and wherein the plurality of dies are coupled with top dies, in accordance with various embodiments. Package 900, which may be similar to package 800 of FIG. 8, is a cross section side view that includes a BGA layer 910, a first RDL 908, an intermediate layer 905, which may include a die or a substrate, a second RDL 906, a mid-die level 904, and a top die layer 902. In embodiments, the mid-die level 904 may include a first mid-die 930 that is electrically and physically coupled with the second RDL 906 using a connection layer 904a and a second mid-die 940 that is electrically and physically coupled with the second RDL 906 using a connection layer 904b.

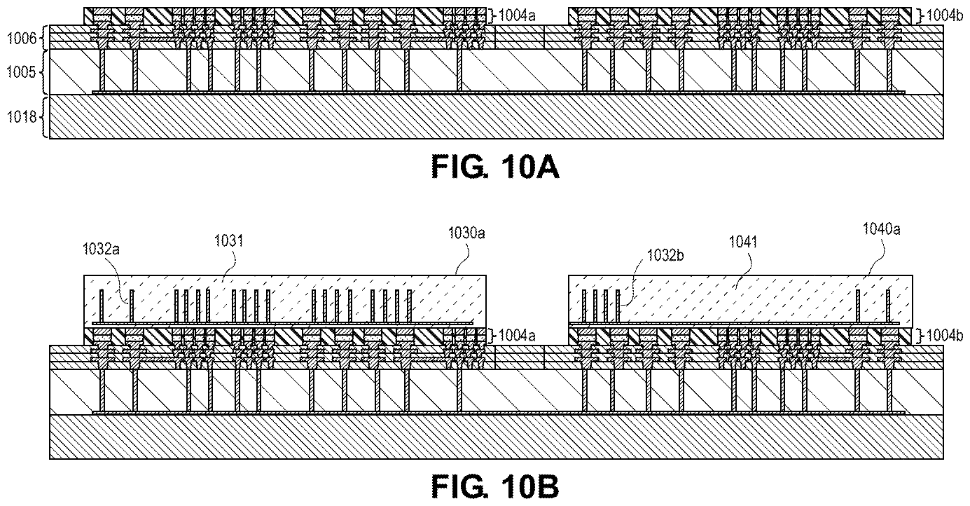

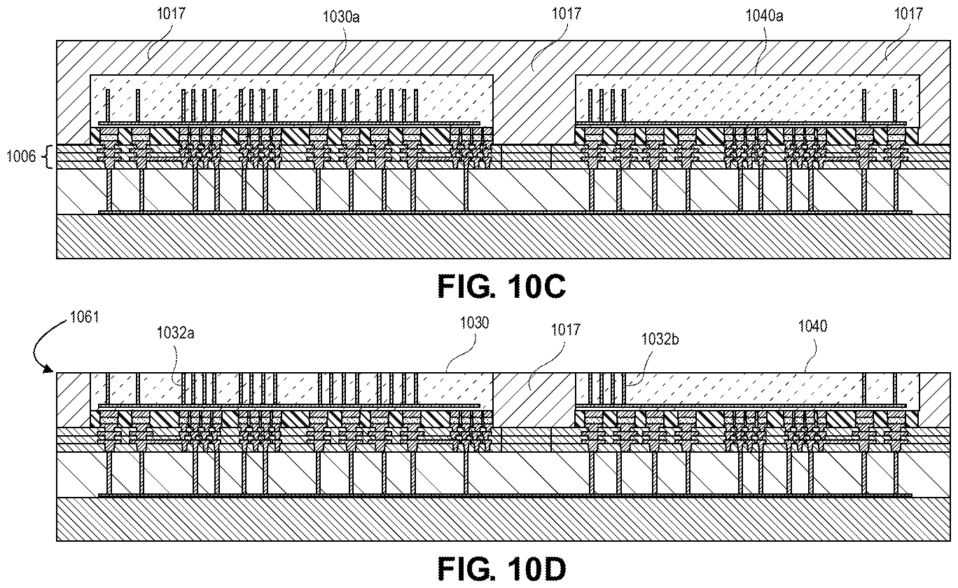

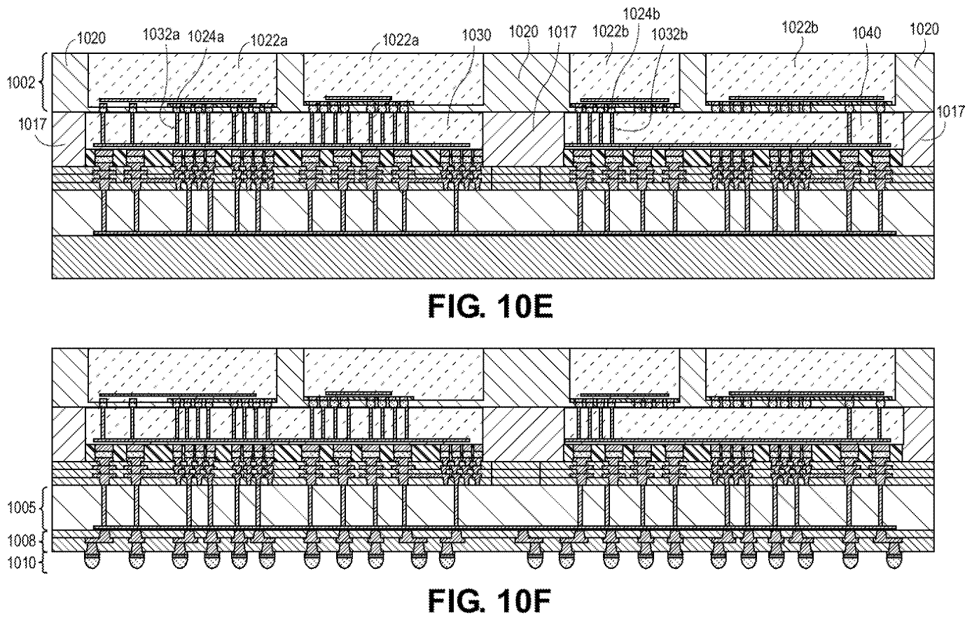

In embodiments, subsequent to the placement of the first mid-die 930 and the second mid-die 940, a first molding 917 may be applied around the first mid-die 930 and the second mid-die 940. Then, a planarization process occurs, described further below with respect to FIGS. 10A-10F. As a result, TSV 932a of the first mid-die 930 are revealed and may be then directly electrically coupled with bumps 924a, and TSV 932b of the second mid-die 940 are revealed and may be directly electrically coupled with bumps 924b. In embodiments, the first molding 917 may extend down to a surface of the second RDL 906.

Subsequently, a second molding 920 may be applied that surrounds the fist mid-die 930, the second mid-die 940, and is on top of the first molding 917. In embodiments, a side of the first molding 917 will be coplanar with a surface of the first mid-die 930 and with a surface of the second mid-die 940.

FIGS. 10A-10F illustrate cross section side views of stages in a manufacturing process for creating a plurality of dies embedded within a layer of molding, where a side of the molding is coplanar with a side of each of the plurality of dies, in accordance with various embodiments. FIG. 10A illustrates a cross section side view of a stage in the manufacturing process where a carrier 1018, which may be a glass carrier, is coupled with an intermediate layer 1005, which may be similar to intermediate layer 905 of FIG. 9. An RDL 1006, which may be similar to second RDL 906 of FIG. 9, may be coupled to the intermediate layer 1005. In embodiments, a first connection layer 1004a and a second connection layer 1004b may be formed and coupled to a side of the RDL 1006.

FIG. 10B illustrates a cross section side view of a stage in the manufacturing process where a first mid-level die 1030a is coupled with the first connection layer 1004a and a second mid-level die 1040a is coupled with the second connection layer 1004b. The first mid-level die 1030a may be similar to first mid-die 930 of FIG. 9, and the second mid-level die 1040a may be similar to second mid-die 940 of FIG. 9.

However, for the first mid-level die 1030a, the die casing 1031 may extend above the TSV 1032a, and for the second mid-level die 1040a the die casing 1041 may extend above the TSV 1032b. For example, the TSV 1032a does not extend through to an edge of the die casing 1031, and the TSV 1032b does not extend through to an edge of the die casing 1041. In embodiments, this is due to the fact that a side of the first mid-level die 1030a and a side of the second mid-level die 1040a have not yet been revealed, or finished.

FIG. 10C illustrates a cross section side view of a stage in the manufacturing process where a first molding 1017, which may be similar to first molding 917 of FIG. 9, is placed around the first mid-level die 1030a, the second mid-level die 1040a, and on the RDL 1006.

FIG. 10D illustrates a cross section side view of a stage in the manufacturing process where a planarization process occurs to remove a portion of the first molding 1017 of FIG. 10C, and a portion of the die casing 1031 of first mid-level die 1030a and a portion of the die casing 1041 of second mid-level die 1040a of FIG. 10B to create plane 1061. In embodiments, the planarization may include a grinding process followed by a polishing process, for example chemical mechanical polishing. As a result, first mid-level die 1030 is formed that include TSV 1032a that are ready to be directly electrically coupled, and second mid-level die 1040 is formed that include TSV 1032b that are ready to be directly electrically coupled. In embodiments, a surface of the first mid-level die 1030, a surface of the second mid-level die 1040, and a surface of the first molding 1017 are in a same plane 1061.

FIG. 10E illustrates a cross section side view of a stage in the manufacturing process where a top die layer 1002, which may be similar to the top die layer 902 of FIG. 9, may be formed. In embodiments, top dies 1022a may be coupled with the first mid-level die 1030 using bumps 1024a that electrically couple with TSV 1032a, and top dies 1022b may be coupled with the second mid-level die 1040 using bumps 1024b that electrically couple with TSV 1032b. Subsequently a second molding 1020 may be applied that surrounds the top dies 1022a, 1022b, and may be on top of first molding 1017.

FIG. 10F illustrates a cross-section side views of a stage in the manufacturing process where the carrier 1018 of FIG. 10A has been removed, and a RDL 1008, which may be similar to first RDL 908 of FIG. 9, is applied to intermediate layer 1005, and a BGA layer 1010, which may be similar to BGA layer 910 of FIG. 9, is applied to the RDL 1008.

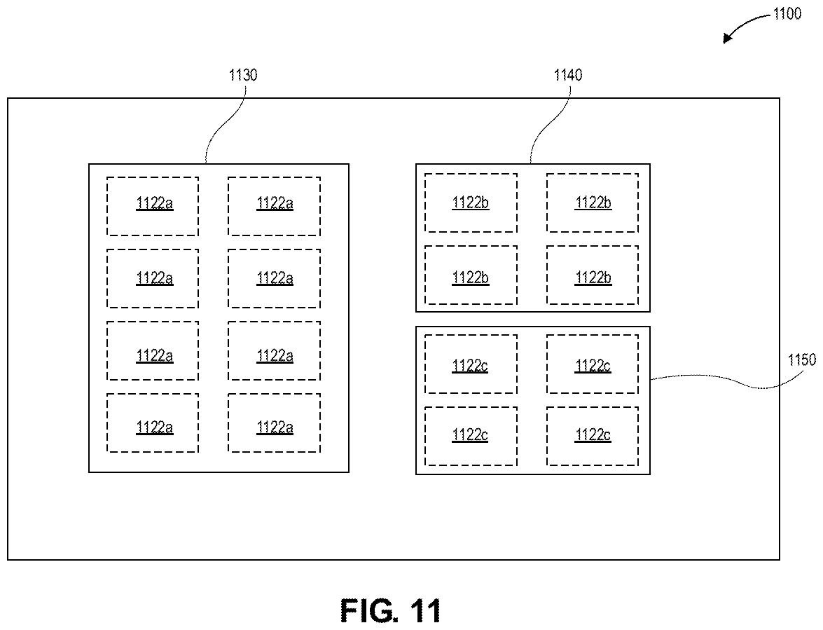

FIG. 11 illustrates a top-down view of a package that includes a plurality of dies embedded within a layer of molding, where a side of the molding is coplanar with a side of each of the plurality of dies, and wherein the plurality dies are coupled with top dies, in accordance with various embodiments. Package 1100, which may be similar to package 900 of FIG. 9, shows a top-down view that includes a first mid-die 1130 which may be similar to first mid-die 930 of FIG. 9, a second mid-die 1140 and a third mid-die 1150, which may be similar to second mid-die 940 of FIG. 9. The first mid-die 1130, the second mid-die 1140, and the third mid-die 1150 may be formed using the techniques described above with respect to FIGS. 10A-10F.

A plurality of top dies 1122a, 1122b, 1122c, which may be similar to top dies 922a or top dies 922b of FIG. 9, may be coupled, respectively, to the first mid-die 1130, the second mid-die 1140, and the third mid-die 1150, to provide conductivity, power, and/or signaling.

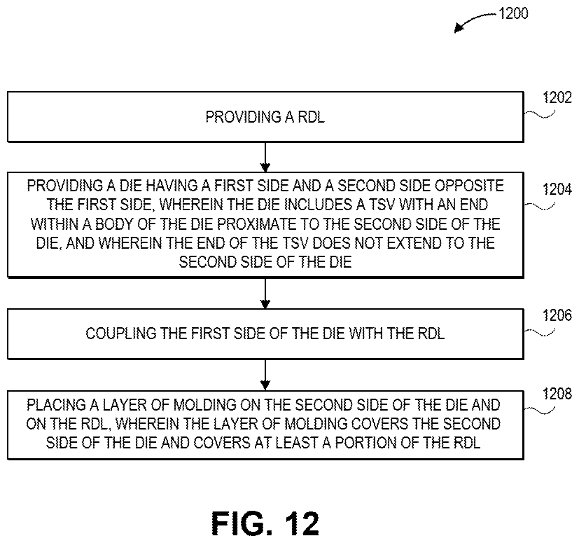

FIG. 12 illustrates an example of a process for creating an embedded die with a side that is coplanar with a side of a molding layer and is electrically coupled with another die, in accordance with various embodiments. In embodiments, process 1200 may be performed using the apparatus, tools, systems, processes, and/or techniques described herein, and in particular with respect to FIGS. 1A-11.

At block 1202, the process may include providing a RDL. In embodiments, the RDL may be similar to the first RDL 308 of FIG. 3A.

At block 1204, the process may further include providing a die having a first side and a second side opposite the first side, wherein the die includes a TSV with an end within a body of the die proximate to the second side of the die, and wherein the end of the TSV does not extend to the second side of the die. In embodiments, the die may be similar to die 331a of FIG. 3A, and the one or more TSV may be similar to TSV 332 of FIG. 3A.

At block 1206, the process may further include coupling the first side of the die with the RDL.

At block 1208, the process may further include placing a layer of molding on the second side of the die and on the RDL, wherein the layer of molding covers the second side of the die and covers at least a portion of the RDL. In embodiments, the layer of molding may be similar to molding 313 of FIG. 3B.

In embodiments described herein, a die that has been encapsulated with molding, and then planarized such a portion of a die is been removed, and the resulting side of the molding is coplanar with a side of the die has been shown within specific examples of a package. However, the specific examples described herein should not be interpreted as limiting the scope of embodiments of one or more dies with a side that is coplanar with a side of a molding.

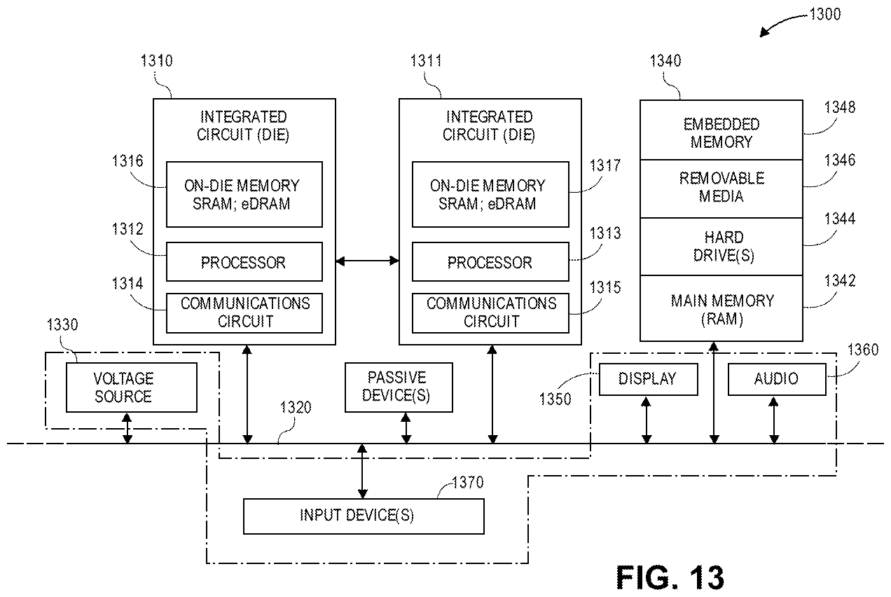

FIG. 13 is a schematic of a computer system 1300, in accordance with an embodiment of the present disclosure. The computer system 1300 (also referred to as the electronic system 1300) as depicted can embody a side of a die that is coplanar with a side of a molding, according to any of the several disclosed embodiments and their equivalents as set forth in this disclosure. The computer system 1300 may be a mobile device such as a netbook computer. The computer system 1300 may be a mobile device such as a wireless smart phone. The computer system 1300 may be a desktop computer. The computer system 1300 may be a hand-held reader. The computer system 1300 may be a server system. The computer system 1300 may be a supercomputer or high-performance computing system.

In an embodiment, the electronic system 1300 is a computer system that includes a system bus 1320 to electrically couple the various components of the electronic system 1300. The system bus 1320 is a single bus or any combination of busses according to various embodiments. The electronic system 1300 includes a voltage source 1330 that provides power to the integrated circuit 1310. In some embodiments, the voltage source 1330 supplies current to the integrated circuit 1310 through the system bus 1320.

The integrated circuit 1310 is electrically coupled to the system bus 1320 and includes any circuit, or combination of circuits according to an embodiment. In an embodiment, the integrated circuit 1310 includes a processor 1312 that can be of any type. As used herein, the processor 1312 may mean any type of circuit such as, but not limited to, a microprocessor, a microcontroller, a graphics processor, a digital signal processor, or another processor. In an embodiment, the processor 1312 includes, or is coupled with, a side of a die that is coplanar with a side of a molding, as disclosed herein. In an embodiment, SRAM embodiments are found in memory caches of the processor. Other types of circuits that can be included in the integrated circuit 1310 are a custom circuit or an application-specific integrated circuit (ASIC), such as a communications circuit 1314 for use in wireless devices such as cellular telephones, smart phones, pagers, portable computers, two-way radios, and similar electronic systems, or a communications circuit for servers. In an embodiment, the integrated circuit 1310 includes on-die memory 1316 such as static random-access memory (SRAM). In an embodiment, the integrated circuit 1310 includes embedded on-die memory 1316 such as embedded dynamic random-access memory (eDRAM).

In an embodiment, the integrated circuit 1310 is complemented with a subsequent integrated circuit 1311. Useful embodiments include a dual processor 1313 and a dual communications circuit 1315 and dual on-die memory 1317 such as SRAM. In an embodiment, the dual integrated circuit 1310 includes embedded on-die memory 1317 such as eDRAM.

In an embodiment, the electronic system 1300 also includes an external memory 1340 that in turn may include one or more memory elements suitable to the particular application, such as a main memory 1342 in the form of RAM, one or more hard drives 1344, and/or one or more drives that handle removable media 1346, such as diskettes, compact disks (CDs), digital variable disks (DVDs), flash memory drives, and other removable media known in the art. The external memory 1340 may also be embedded memory 1348 such as the first die in a die stack, according to an embodiment.

In an embodiment, the electronic system 1300 also includes a display device 1350, an audio output 1360. In an embodiment, the electronic system 1300 includes an input device such as a controller 1370 that may be a keyboard, mouse, trackball, game controller, microphone, voice-recognition device, or any other input device that inputs information into the electronic system 1300. In an embodiment, an input device 1370 is a camera. In an embodiment, an input device 1370 is a digital sound recorder. In an embodiment, an input device 1370 is a camera and a digital sound recorder.

As shown herein, the integrated circuit 1310 can be implemented in a number of different embodiments, including a package substrate having a side of a die that is coplanar with a side of a molding, according to any of the several disclosed embodiments and their equivalents, an electronic system, a computer system, one or more methods of fabricating an integrated circuit, and one or more methods of fabricating an electronic assembly that includes a package substrate having a side of a die that is coplanar with a side of a molding, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a side of a die that is coplanar with a side of a molding embodiments and their equivalents. A foundation substrate may be included, as represented by the dashed line of FIG. 13. Passive devices may also be included, as is also depicted in FIG. 13.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope is to be determined entirely by the following claims, which are to be construed in accordance with established doctrines of claim interpretation.

### EXAMPLES

The following paragraphs describe examples of various embodiments.

Example 1 is a package comprising: a layer of molding; a die in the layer of molding; a through silicon via (TSV) within the die, wherein an end of the TSV is at a side of the die; and wherein a surface of the side of the die is in a same plane as a surface of a side of the layer of molding.

Example 2 includes the package of example 1, wherein the layer of molding is not in direct physical contact with the end of the TSV.

Example 3 includes the package of examples 1 or 2, wherein the TSV is a plurality of TSV.

Example 4 includes the package of examples 1, 2, or 3, wherein the TSV includes copper.

Example 5 includes the package of examples 1, 2, 3, or 4, further comprising a redistribution layer on the side of the die and on the side of the layer of molding, wherein the redistribution layer is directly electrically coupled with the end of the TSV.

Example 6 includes the package of example 5, wherein the die includes a front side routing layer, and wherein the front side routing layer in the die is electrically coupled with the TSV.

Example 7 includes the package of example 6, wherein the side of the die is a first side; and further comprising a second side of the die opposite the first side, wherein the second side of the die includes one or more electrically conductive features, and wherein the one or more electrically conductive features are electrically coupled with the front side routing layer of the die.

Example 8 includes the package of example 7, wherein the redistribution layer is a first redistribution layer; and further comprising a second redistribution layer electrically coupled with the one or more electrically conductive features on the second side of the die.

Example 9 includes the package of example 8, wherein the layer of molding extends from the first redistribution layer to the second redistribution layer.

Example 10 includes the package of example 9, further comprising one or more copper pillars that electrically couple the first redistribution layer and the second redistribution layer, wherein the one or more copper pillars are within the layer of molding.

Example 11 includes the package of examples 1, 2, 3, 4, 5, 6, 7, 8, 9, or 10, wherein the die is a plurality of dies.

Example 12 is a package comprising: a redistribution layer; a die on the redistribution layer, wherein the die includes one or more TSV, wherein each end of the one or more TSV is at a side of the die next to the redistribution layer, and wherein each end of the one or more TSV directly electrically couple with a side of the redistribution layer; and a layer of molding on the side of the redistribution layer and at least partially surrounding the die, wherein a surface of the layer of molding at the side of the redistribution layer is in a same plane as a surface of the side of the die.

Example 13 includes the package of example 12, wherein the side of the die is a first side of the die; and further comprising a second side of the die opposite the first side of the die, wherein the layer of molding extends to the second side of the die.

Example 14 includes the package of example 13, wherein the die is a first die; and further comprising a second die, wherein the second die is on the second side of the first die.

Example 15 includes the package of examples 12, 13, or 14, wherein the one or more TSV are filled with copper.

Example 16 includes the package of examples 12, 13, 14, or 15, wherein the side of the redistribution layer is a first side; and further comprising: a second side of the redistribution layer opposite the first side; and a ball grid array electrically coupled with the second side of the redistribution layer.

Example 17 is a method for creating a package, the method comprising: providing a redistribution layer (RDL); providing a die having a first side and a second side opposite the first side, wherein the die includes a through silicon via (TSV) with an end within a body of the die proximate to the second side of the die, and wherein the end of the TSV does not extend to the second side of the die; coupling the first side of the die with the RDL; and placing a layer of molding on the second side of the die and on the RDL, wherein the layer of molding covers the second side of the die and covers at least a portion of the RDL.

Example 18 includes the method of example 17, further comprising performing a planarization of the layer of molding and of the die, wherein the planarization includes removing a portion of the molding forming a planarized surface of the layer of molding and removing the second side of the die forming a planarized surface of the die that exposes the TSV at the planarized surface of the die.

Example 19 includes the method of example 18, wherein the planarized surface of the layer of molding and the planarized surface of the die are in a same plane.

Example 20 includes the method of examples 18 or 19, wherein the die is a first die; and further comprising electrically coupling a second die with the exposed TSV at the planarized surface of the first die.

What is claimed is:

1. A package, comprising:
a first redistribution layer (RDL);
a first die over and coupled to the first RDL, the first die having a through silicon via (TSV) therein;
a second die over and coupled to the first RDL, the second die laterally spaced apart from the first die;
a third die over and coupled to the first RDL, the third die laterally spaced apart from the second die, and the second die laterally between the first die and the third die, the third die having a TSV therein;
a molding layer laterally adjacent to and in contact with the first die, the second die, and the third die, the molding layer on the first RDL;
a second RDL over and coupled to the first die, the second die, and the third die, the second RDL on the molding layer;
a fourth die over and coupled to the second RDL, wherein the first die is entirely within a lateral width of the fourth die, and wherein the second die is partially within the lateral width of the fourth die;
a fifth die over and coupled to the second RDL, the fifth die laterally spaced apart from the fourth die, wherein the third die is entirely within a lateral width of the fifth die, and wherein the second die is partially within the lateral width of the fifth die;
a first copper pillar in the molding layer beneath the fourth die and laterally spaced apart from the first die, wherein the first copper pillar couples the second RDL to the first RDL;
a second copper pillar in the molding layer beneath the fifth die and laterally spaced apart from the third die, wherein the second copper pillar couples the second RDL to the first RDL; and
a molding laterally between and in contact with the fourth die and the fifth die.

2. The package of claim 1, wherein the fourth die has an uppermost surface at a same level as an uppermost surface of the fifth die.

3. The package of claim 1, wherein the fourth die has a bottommost surface at a same level as a bottommost surface of the fifth die.

4. The package of claim 1, wherein the first die has a bottommost surface at a same level as a bottommost surface of the molding layer.

5. The package of claim 1, further comprising:
a third copper pillar in the molding layer beneath the fourth die and laterally spaced apart from a side of the first die opposite the first copper pillar, wherein the third copper pillar couples the second RDL to the first RDL.

6. The package of claim 5, further comprising:
a fourth copper pillar in the molding layer beneath the fifth die and laterally spaced apart from a side of the third die opposite the second copper pillar, wherein the fourth copper pillar couples the second RDL to the first RDL.

7. The package of claim 1, wherein the molding laterally surrounds the fourth die and the fifth die.

8. A package, comprising:
a first redistribution layer (RDL);
a mid-layer on the first RDL, the mid-layer comprising a first die over and coupled to the first RDL, a second die over and coupled to the first RDL, the second die laterally spaced apart from the first die, a third die over and coupled to the first RDL, the third die laterally spaced apart from the second die, and the second die laterally between the first die and the third die, a molding layer laterally adjacent to and in contact with the first die, the second die, and the third die, the molding layer on the first RDL, a first copper pillar in the molding layer and laterally spaced apart from the first die, and a second copper pillar in the molding layer and laterally spaced apart from the third die, wherein the first die has a through silicon via (TSV) therein and coupled to the first RDL, and the third die has a TSV therein and coupled to the first RDL;
a second RDL on the mid-layer, the second RDL and coupled to the first die, the second die, and the third die, wherein the first copper pillar of the mid-layer couples the second RDL to the first RDL, and the second copper pillar of the mid-layer couples the second RDL to the first RDL; and
a top die layer on the second RDL, the top die layer comprising a fourth die coupled to the second RDL, a fifth die coupled to the second RDL, the fifth die laterally spaced apart from the fourth die, and a molding laterally between and in contact with the fourth die and the fifth die, wherein the first die of the mid-layer is entirely within a lateral width of the fourth die, wherein the second die of the mid-layer is partially within the lateral width of the fourth die, wherein the third die of the mid-layer is entirely within a lateral width of the fifth die, wherein the second die of the mid-layer is partially within the lateral width of the fifth die, wherein the first copper pillars is beneath the fourth die, and the second copper pillar is beneath the fifth die.

9. The package of claim 8, wherein the fourth die of the top die layer has an uppermost surface at a same level as an uppermost surface of the fifth die of the top die layer.

10. The package of claim 8, wherein the fourth die of the top die layer has a bottommost surface at a same level as a bottommost surface of the fifth die of the top die layer.

11. The package of claim 8, wherein the first die of the mid-layer has a bottommost surface at a same level as a bottommost surface of the molding layer of the mid-layer.

12. The package of claim 8, wherein the mid-layer further comprises:
a third copper pillar in the molding layer beneath the fourth die and laterally spaced apart from a side of the first die opposite the first copper pillar, wherein the third copper pillar couples the second RDL to the first RDL; and
a fourth copper pillar in the molding layer beneath the fifth die and laterally spaced apart from a side of the third die opposite the second copper pillar, wherein the fourth copper pillar couples the second RDL to the first RDL.

13. The package of claim 8, wherein the molding of the top die layer laterally surrounds the fourth die of the top die layer and the fifth die of the top die layer.

14. A method of fabricating a package, the method comprising:
forming a first redistribution layer (RDL);
providing a first die over and coupled to the first RDL, the first die having a through silicon via (TSV) therein;
providing a second die over and coupled to the first RDL, the second die laterally spaced apart from the first die;
providing a third die over and coupled to the first RDL, the third die laterally spaced apart from the second die, and the second die laterally between the first die and the third die, the third die having a TSV therein;
forming a molding layer laterally adjacent to and in contact with the first die, the second die, and the third die, the molding layer on the first RDL;
forming a second RDL over and coupled to the first die, the second die, and the third die, the second RDL on the molding layer;
providing a fourth die over and coupled to the second RDL, wherein the first die is entirely within a lateral width of the fourth die, and wherein the second die is partially within the lateral width of the fourth die;
providing a fifth die over and coupled to the second RDL, the fifth die laterally spaced apart from the fourth die, wherein the third die is entirely within a lateral width of the fifth die, and wherein the second die is partially within the lateral width of the fifth die;
forming a first copper pillar in the molding layer beneath the fourth die and laterally spaced apart from the first die, wherein the first copper pillar couples the second RDL to the first RDL;
forming a second copper pillar in the molding layer beneath the fifth die and laterally spaced apart from the third die, wherein the second copper pillar couples the second RDL to the first RDL; and
forming a molding laterally between and in contact with the fourth die and the fifth die.

15. The method of claim 14, wherein the fourth die has an uppermost surface at a same level as an uppermost surface of the fifth die.

16. The method of claim 14, wherein the fourth die has a bottommost surface at a same level as a bottommost surface of the fifth die.

17. The method of claim 14, wherein the first die has a bottommost surface at a same level as a bottommost surface of the molding layer.

18. The method of claim 14, further comprising:
forming a third copper pillar in the molding layer beneath the fourth die and laterally spaced apart from a side of the first die opposite the first copper pillar, wherein the third copper pillar couples the second RDL to the first RDL.

19. The method of claim 18, further comprising:
forming a fourth copper pillar in the molding layer beneath the fifth die and laterally spaced apart from a side of the third die opposite the second copper pillar, wherein the fourth copper pillar couples the second RDL to the first RDL.

20. The method of claim 14, wherein the molding laterally surrounds the fourth die and the fifth die.
